(19) United States
(12) Patent Application Publication
(10) Pub. No.: US 2003/0117948 A1
(43) Pub. Date: Jun. 26, 2003

(54) Method and gateway GPRS support node (GGSN) for control plane redundancy

(76) Inventors: Bobby That Dao Ton, Lachine (CA); Tormod Hegdahl, Moserabben (NO); Lev Deich, Brossard (CA)

Correspondence Address: SANDRA BEAUCHESNE, Ericsson Canada Inc., Patent Department (LMC/UP), 8400 Decarie Blvd., Town Mount Royal, QC, H4P 2N2, CA

(21) Appl. No.: 10/025,750

(22) Filed: Dec. 26, 2001

(51) Int. Cl. G01R 31/08; H04Q 7/00; H04L 12/28

(52) U.S. Cl. 370/218; 370/401; 370/328; 455/13.1

(57) ABSTRACT

A GPRS Support Node (GGSN) has a plurality of slave data session control units (GTP-C/s) for controlling data sessions for Mobile Stations (MSs), a plurality of data sessions payload units (GTP-Us) for supporting routing of data sessions payloads, and a master data session control unit (GTP-C/m) dispatching data sessions requests to GTP-C/s. When a GTP-C/s goes down, the GTP-C/m detects the failure, closes data sessions of the failed GTP-C/s and their corresponding accounting sessions. If a spare control unit is available, the GTP-C/m detects and activates the spare unit with the role and IP address of the failed GTP-C/s. When the GTP-C/m goes down, all the control units are notified, and the least loaded unit is elected for replacing the GTP-C/m. The elected unit is a spare, non-utilized, GTP-C, or one of the slave GTP-C/s, which is activated as the GTP-C/m by rebuilding a GTP-C/m database with information received from remaining GTP-C/s.

### BACKGROUND OF THE INVENTION

1. Field of the Invention

The present invention relates to GPRS networks, and in particular to a Gateway GPRS Support Node (GGSN).

2. Description of the Related Art

General Packet Radio Services (GPRS) is a packet-based wireless communication service that offers higher data rates and continuous connection to an Internet Protocol (IP) data network for mobile phone and computer users. The higher data rates allow users to take part in videoconferences and interact with multimedia Web sites and similar applications using mobile terminal devices as well as notebook computers. GPRS is an evolution of the Global System for Mobile (GSM) communications and complements existing services such as the circuit-switched cellular phone connections and the Short Message Service (SMS).

In GPRS packet-based service communication channels are used on a shared-use, as-packets-are-needed basis rather than dedicated only to one user at a time. As GPRS becomes available, mobile users of a Virtual Private Network (VPN) are able to access privates network continuously rather than through a dial-up connection. GPRS also complements Bluetooth, a standard for replacing wired connections between devices with wireless radio connections. GPRS is an evolutionary step toward the Third Generation (3G) Enhanced Data GSM Environment (EDGE) and Universal Mobile Telephone Service (UMTS).

Reference is now made to FIG. 1 (Prior Art), which shows a high-level logical architecture diagram of a typical GPRS network 100, with the standard accepted nodes, functionalities and interfaces. The functioning of the illustrated network is known in the art, as described in the Third Generation Partnership Project (3GPP)′ GPRS standards Release 99, herein included by reference. For example, shown in FIG. 1 is a Serving GPRS Support Node (SGSN) 102 that provides the direct access point for GPRS-based terminals, subtending from one or more Gateway GPRS Support Nodes (GGSNs) 104ᵢ, that provide the gateway to the SGSN across mobile networks that the user may visit. The GGSNs 104ᵢ are one of the key components of GPRS core network, being the anchor points for the mobile GPRS terminals to which they provide support for seamless IP connectivity. The GGSNs support access for the Mobile Stations (MS) towards multiple Packet-Data networks (PDN), such as for corporate/ISPs (Internet Service Providers) 108, by using Virtual Private Network (VPN) technologies. Corporate/ISP selection by the MS, utilise the Access Point Name (APN) information element to create GPRS Tunnelling Protocol (GTP) message such as defined in the Third Generation Partnership Project (3GPP) Technical Specification (TS) 29.060 of Release 99, and in the GSM 09.60 of same Release 99, both of which are herein included by reference, in the setting up of sessions through the GPRS network. The communications between the MS 106 and the GGSN 104 are connection oriented and hence continuous support of a GTP data session in the GGSN is of utmost importance for the user's service acceptance. The GGSN receives IP datagrams routed to the Packet Data Protocol (PDP) address of any of its connected MSs, and tunnels those IP datagrams for delivery to the MS via the GTP tunnel (i.e. through the SGSN). The GGSN is connected to the SGSN via an IP backbone.

Therefore, the availability of the GGSN is critical for the continuous provision of data services in the GPRS network. However, the existing platforms on which the GGSN functionality is implemented do not provide platform redundancy. Consequently, in current GGSN implementations, in case of failure of a software module, or of a hardware component of the GGSN, the GPRS/UMTS service is interrupted until the failed GGSN recovers.

Accordingly, it would be advantageous to have a GGSN having a distributed architecture allowing a control plane redundancy that avoids the total collapse of the GGSN in case a given hardware or software component of the GGSN experiences a failure. The present invention provides such a method and system.

### SUMMARY OF THE INVENTION

In one aspect, the present invention is a method for replacing a failed data session slave control unit (GTP-C/s) in a Gateway General Packet Radio Service (GPRS) Support Node (GGSN), the method comprising the steps of:

detecting a failure or a shutdown of the GTP-C/s in the GGSN;

detecting if the failed GTP-C/s controlled any data sessions before it failed;

if the failed GTP-C/s controlled any data sessions before it failed, closing all the data sessions and accounting sessions related to the data sessions.

In another aspect, the present invention is a method for replacing a failed data session master control unit (GTP-C/m) in a Gateway General Packet Radio Service (GPRS) Support Node (GGSN), the method comprising the steps of:

detecting a failure or a shutdown of the GTP-C/m in the GGSN;

detecting, among all remaining data session control units (GTP-C) available in the GGSN, the GTP-C with the least load, and electing the GTP-C with the least load as a fail-over unit for the GTP-C/m that failed;

recovering by the elected GTP-C information related to the failed GTP-C/m from other GTP-C units;

rebuilding by the elected GTP-C a GTP-C/m information database using the information related to the failed GTP-C/m; and

starting the elected GTP-C as a GTP-C/m of the GGSN.

In yet another aspect, the present invention is a Gateway General Packet Radio Service (GPRS) Support Node (GGSN), comprising:

a plurality of slave data session control units (GTP-C/s), each being set to controlling a plurality of data sessions for Mobile Stations (MSs);

a plurality of data sessions payload units (GTP-Us) for supporting a routing of a payload of the data sessions; and

a master data session control unit (GTP-C/m) detecting a failure or a shutdown of one of the GTP-C/s of the GGSN, the GTP-C/m further detecting if the failed GTP-C/s controlled any data sessions before it failed, and if the failed GTP-C/s controlled any data sessions before it failed, the GTP-C/m requesting from the plurality of GTP-Us to close all the data sessions;

wherein the GTP-Us respond to the request by closing all accounting sessions related to the data sessions.

In yet another aspect, the present invention is a Gateway General Packet Radio Service (GPRS) Support Node (GGSN), comprising:

a master data session control unit (GTP-C/m);

a plurality of data session control units (GTP-Cs); and

a Routing Engine (RE) detecting a failure or a shutdown of the GTP-C/m;

wherein the RE in combination with all remaining GTP-Cs available in the GGSN further detect the GTP-C with the least load, and elect the GTP-C with the least load as a fail-over unit for the GTP-C/m that failed, and wherein the elected GTP-C recovers information related to the failed GTP-C/m from the remaining GTP-C units, rebuilds a GTP-C/m information database using the information related to the failed GTP-C/m, and starts acting as a GTP-C/m of the GGSN.

### BRIEF DESCRIPTION OF THE DRAWINGS

For a more detailed understanding of the invention, for further objects and advantages thereof, reference can now be made to the following description, taken in conjunction with the accompanying drawings, in which:

FIG. 1 (Prior Art) is a high-level logical architecture diagram of a typical GPRS network as it is known in the prior art;

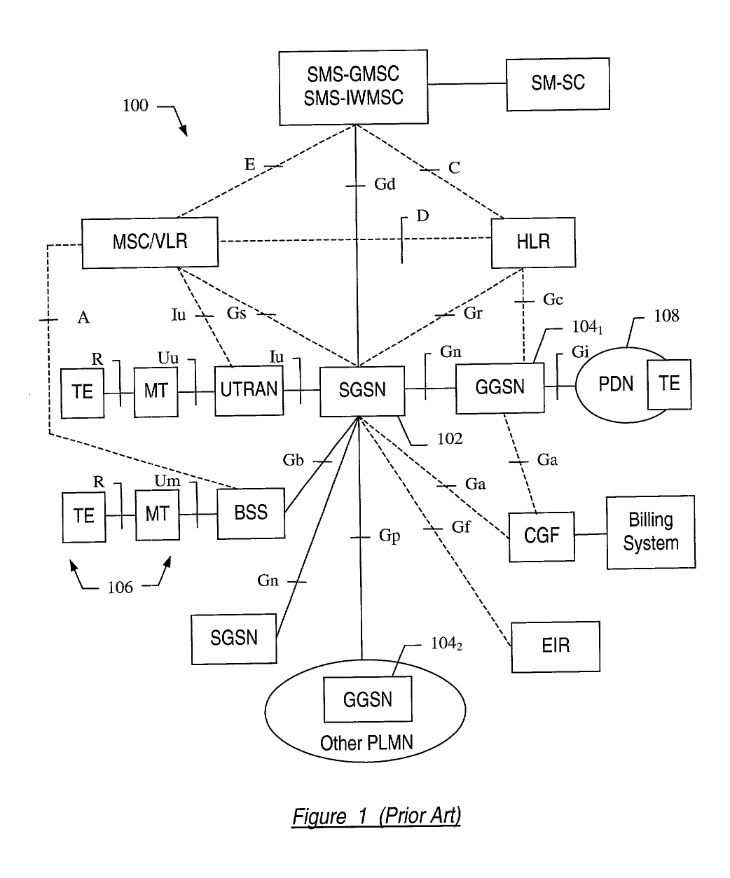

FIG. 2 is an exemplary nodal architecture diagram of a Gateway GPRS Support Node (GGSN) according to the preferred embodiment of the invention;

FIG. 3 is an exemplary nodal operation and signal flow diagram of one aspect of the preferred embodiment of the invention;

FIG. 4 is another exemplary nodal operation and signal flow diagram of another aspect of the preferred embodiment of the invention; and

FIG. 5 is yet another exemplary nodal operation and signal flow diagram of yet another aspect of the preferred embodiment of the invention.

### DETAILED DESCRIPTION OF THE PREFERRED EMBODIMENTS

The innovative teachings of the present invention will be described with particular reference to numerous exemplary embodiments. However, it should be understood that this class of embodiments provides only a few examples of the many advantageous uses of the innovative teachings of the invention. In general, statements made in the specification of the present application do not necessarily limit any of the various claimed aspects of the present invention. Moreover, some statements may apply to some inventive features but not to others. In the drawings, like or similar elements are designated with identical reference numerals throughout the several views, and the various elements depicted are not necessarily drawn to scale.

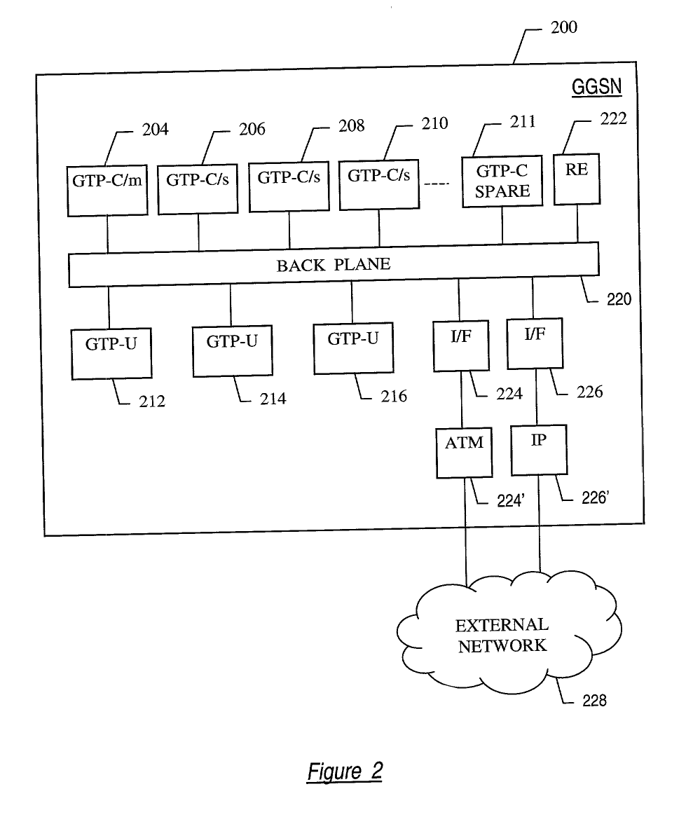

Referring now to FIG. 2, depicted therein is an exemplary nodal architecture diagram of a Gateway GPRS Support Node (GGSN) 200 according to the preferred embodiment of the invention. The GGSN 200 comprises a distributed GGSN control plane functionality (GTP-C) 202 having multiple control processing units (GTP-Cs) 204-210 for communication sessions control handling. Preferably, the GTP-Cs are processing cards that control one or more Point-to-Point Protocol (PPP) data sessions for mobile terminals. Their main functions include charging (billing), processing the create GPRS Tunnelling Protocol (GTP) control messages related to each data session they control, and providing a Remote Authentication Dial-In User Server/Service (RADIUS) interface for user authentication. The GGSN 200 further comprises multiple communications (data session) payload processing units (GTP-Us) 212-216 which functions include handling the data sessions payload and of the GTP tunnelling and de-tunnelling for each data session they handle. The distributed GGSN control plane functionality (GTP-C) 202 of the GGSN 200 may also comprise a spare, non-utilized, GTP-C unit 211 that runs in a stand-by mode and is ready for taking over the control tasks of a failed GTP-C unit. This distributed architecture provides reliability and scalability to the GGSN 200, and hence reduces the service downtime in case of a single point of failure in one of the GTP-Cs. The GGSN 200 further includes a back-plane 220 acting as a communications bus connecting the different components of the GGSN 200. A Routing Engine (RE) 222 is responsible for managing a routing table (not shown) allowing the correct internal signalling and communications between the different components of the GGSN 200. Communications interfaces I/F 224 and 226 provide access for the GGSN 200 to external networks 228 selected by the users, or to cooperating GGSNs.

According to the present invention, the GGSN 200 provides support for load balancing and control task distribution between the active GTP-Cs, as it also provides support for load balancing and data sessions distribution between the active GTP-Us. A centralized PDP context management for the whole GGSN control plane offers an efficient method for load balancing and redundancy. Accordingly, all primary PDP contexts create requests are addressed to a master GTP-C unit (GTP-C/m) 204, which thereafter dynamically dispatches the request messages to other slave GTP-Cs (GTP-C/s) 206-210. Subsequent communications for the same link (Primary PDP context and associated secondary PDP context) between a served Mobile Station (MS) and the GGSN 200 are directly addressed to the appropriate GTP-C/s by utilising a GGSN address for control plane information element in the GTP create response message, formatted for example according to the Third Generation Partnership Project (3GPP) Technical Specification (TS) 29.060/GSM 09.060, herein included by reference.

The GTP-C/m and GTP-C/s can use broadcast, multicast messages or similar mechanism to exchange information with each other and between the unit boards for the support of load balancing and GTP-C redundancy. According to the invention, the heartbeat message exchange may have two sets of information with different urgency. First a keep-alive information is used to update cooperating units within less then, for example, 100 milliseconds at both hardware or software failure. The keep-alive information is used to detect addition, removal and failure on the boards of the node. Second, load information may be updated with a frequency of every more or less 1 second to distribute load information from the GTP-C/s and GTP-Us. For efficiency purposes, according to the invention, the keep alive message exchange may be handled on low software level (kernel) in each board and may only be reported to a higher level supervision function (not shown), for actions, at an addition, removal and/or failure situation in the other parts of the node. The load information, reported with less frequency includes relevant load information for the processor units, is periodically distributed between all the GTP-C/s 216-210 and also to the GTP-C/m 204 to indicate their current individual load. The GTP-C/m 204 and each GTP-C/s 206-210 keep the load information from other GTP-C/s locally. The GTP-C/m 204 also keeps the load information from the GTP-Us 212-216. For example, the local load information may contain at least the following fields per processor unit:

1. GTP-C/s Identifier (IP address or GTP-C other ID internally used to uniquely identify a board);

2. Current number of active PDP contexts and/or CPU utilisation (memory utilisation, average present queue length, average present CPU load);

3. Expected maximum capacity or hardware version number;

4. Unit Restart and rebuild information;

The GTP-C/m stores a minimum set of information related to the PDP context in such a way that the GTP-C/s information can be re-build in combination with the information stored on the GTP-U, when such a GTP-C/s unit fails, in a manner yet to be described.

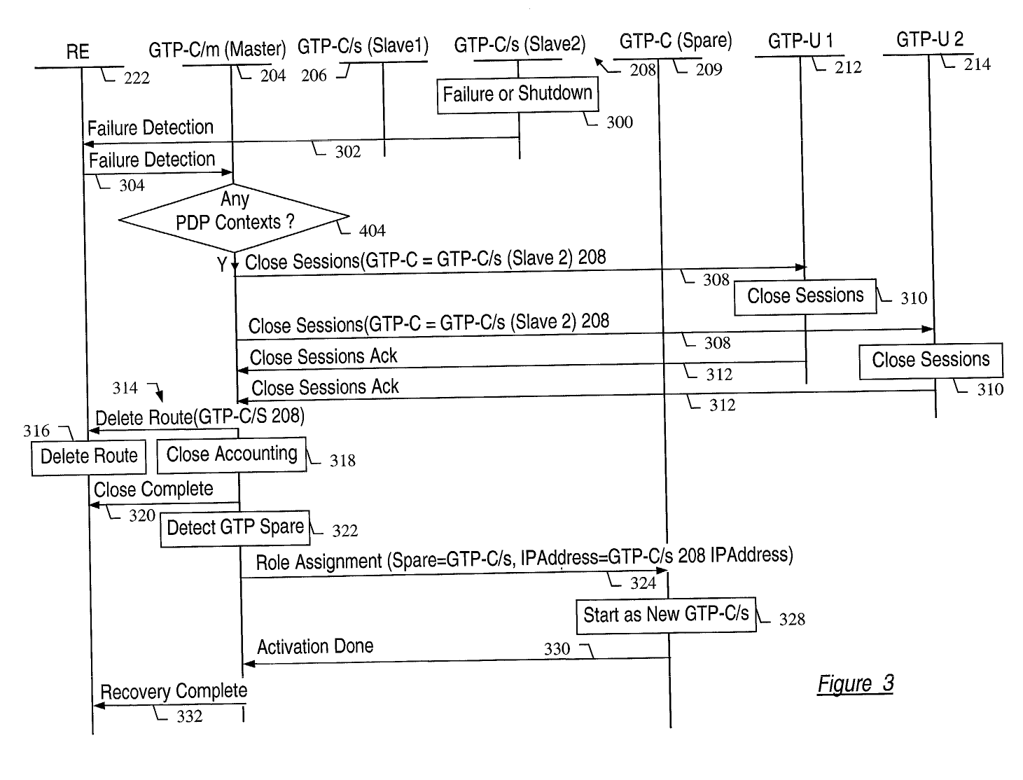

Reference is now made to FIG. 3, wherein there is shown an exemplary nodal operation and signal flow diagram of one aspect of the preferred embodiment of the invention directed to a recovery scheme of a failed GTP-C/s (slave) unit of the GGSN 200 that has a spare, un-utilized GTP-C. In FIG. 3, the shown exemplary nodal operation and signal flow diagram illustrates the same GGSN 200 having the same components as those described with reference to FIG. 2. At the beginning, it is assumed that the GGSN 200 functions normally, wherein each GTP-C/s control one or more data communications sessions, which payload is processed by a corresponding GTP-U. At one point in time, one of the GTP-C/s, such as for example the GTP-C/s (slave 2) 208 experiences a failure, or for a given reason is shut down by the operator, action 300. Following the failure, via the heartbeat (keep-alive) signal sent by the other GTP-C units, or because of the lack of heartbeat signal (keep-alive) sent by the failed GTP-C 208, the Routing Engine (RE) 222 is informed of the failure or shutdown of the GTP-C 208, action 302, which in turn informs the GTP-C/m (master) unit 204, action 304. Since the GTP-C/m comprises a list of all active PDP contexts of the GGSN 200, in action 306, it may detect whether or not the failed GTP-C 208 was controlling any active data communications sessions by detecting if the given GTP-C contained any PDP context information. If so, in action 308, the GTP-C/m sends to all GTP-Us 212 and 214 a Close Sessions message with a parameter having the identity of the failed GTP-C/s 208, thus instructing all GTP-Us to close all data communications sessions that were previously controlled by the GTP-C/s 208 that failed. In actions 310, the GTP-Us 212 and 214 close the data communications sessions previously controlled by the GTP-C 208 that failed, and acknowledge completion of this fact by sending a Close Sessions Acknowledgement message to GTP-C/m 204, actions 312. The GTP-C/m 204 then signals the RE 222 with a Delete Route message 314 requesting the deletion from the routing table (not shown) of the routes related to the data sessions closed in action 310, which the RE 222 does in action 316. The GTP-C/m 204 further closes the accounting sessions related to the data communications sessions which control was held by the failed GTP-C/s 208, action 318, and further reports this fact to the RE 222, action 320.

The GGSN 200 comprises a spare, non-utilized, GTP-C unit 209, that is run in stand-by mode (ready to be used) and that is identified by the GTP-C/m 204 as a spare GTP-C. In action 322, the GTP-C/m 204 detects, or may be otherwise informed of the presence of the GTP-C spare 209, and further performs an activation of the GTP-C spare 209, action 324, by sending a Role Assignment message to the GTP-C spare 209, the message comprising the new role for the GTP-C spare (role=GTP-C/s slave) and the new IP address assigned to the GTP-C, which is the same that the one of the failed GTP-C/s 208. Therefore, the GTP-C spare 209 is set-up as a regular slave GTP-C/s unit by allocating it the IP-address of the failed GTP-C/s 209. In action 328, the newly set up GTP-C/s 209 starts functioning as an active GTP-C/s unit. Finally, the new GTP-C/s 209 send to the GTP-C/m 204 an Activation Done message 330, and the GTP-C/m 204 sends a Recovery Complete message 332 to the RE 222 for informing of the completion of the set-up of the spare GTP-C as a GTP-C/s.

Based upon the foregoing, it should now be apparent to those of ordinary skill in the art that the present invention provides an advantageous solution, which offers GTP-C/s unit redundancy, by quickly activating a spare, non-utilized, GTP-C unit in instances of failure or shutdown of an active GTP-C/s unit. Further, the present invention provides an advantageous scheme wherein most of the data communications sessions held by the plurality of GTP-C/s units of the GGSN 200 are kept alive in case of a single point of failure of one of the GTP-C/s units, and wherein only those data communications sessions controlled by the failed GTP-C/s are lost.

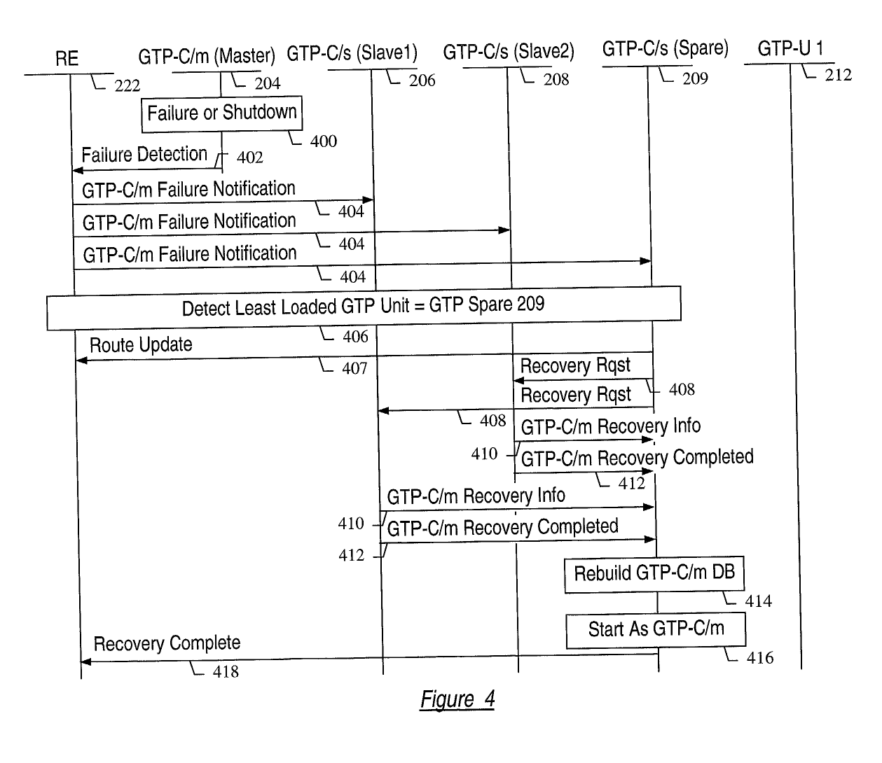

Reference is now made to FIG. 4, wherein there is shown an exemplary nodal operation and signal flow diagram of another aspect of the preferred embodiment of the invention directed to a recovery scheme following the failure of the GTP-C/m 204 of the GGSN 200 that has a spare, un-utilized GTP-C 209. In FIG. 4, the shown exemplary nodal operation and signal flow diagram illustrates the same GGSN 200 having the same components as those described with reference to FIG. 2 and 3. At the beginning, it is assumed that the GGSN 200 functions normally by supporting a number of data communications sessions, as described hereinbefore. At one point in time, the GTP-C/m (master) unit 204 experiences a failure, or for a given reason is shut down by the operator, action 400. Following the failure or shutdown 400, via the heartbeat (keep-alive) signal sent by the other GTP-C units, or because of the lack of heartbeat signal (keep-alive) sent by the failed GTP-C/m 204, the RE 222 is informed of the failure or shutdown of the GTP-C 208, action 402. In action 404, the RE 222 informs all the GTP-C units 206, 208, and 209, that the GTP-C/m 204 is down, and in action 406, the GTP-C with the least load among all available GTP-C units is detected. In the present case, the GTP-C spare 209 is the GTP-C with the least load among all available GTP-C units, since it held no active PDP context information. Following the election of the GTP-C spare 209 as the least loaded GTP-C unit, and by consequence its election as a fail-over unit, the GTP-C spare 209 sends a Route Update message 407 for requesting the RE to update the routing table (not shown) in order to reflect the fact that the GTP-C/s spare is from now on acting as a GTP-C/m. Then, the GTP-C spare 209 sends a GTP-C/m Recovery Request message 408 to all remaining active GTP-C/s 206 and 208, in order to acquire from them all pertinent information that was originally stored in the GTP-C/mn 204 that is now failed. Responsive to the request 408, the GTP-C spare 209 receives from each active GTP-C/s a GTP-C/m Recovery Information 411 comprising information related to the identification and control of the data sessions handled by each GTP-C/s, such as for example, but not limited to the Access Point Name (APN), the GTP-U identification of the GTP-U that processes the payload of each session, etc. Each one of the GTP-C/s 206 and 208 then confirm the end of the transmission of the GTP-C/m Recovery Information by a GTP-C/m Recovery Completed message 412. Having received the appropriate GTP-C/m Recovery Information, the GTP-C spare 209 rebuilds the GTP-C/m information database in action 414, and starts acting as a GTP-C/m (master) unit, action 416. Finally, the newly rebuild GTP-C/m 209 sends a Recovery Complete message 418 to the RE 222 for informing of the completion of the rebuild process.

Based upon the foregoing, it should now be apparent to those of ordinary skill in the art that the present invention provides an advantageous solution, which offers GTP-C/m redundancy, by quickly activating a spare, non-utilized, GTP-C unit as an active GTP-C/m (master) unit in instances of failure or shutdown of the active GTP-C/m. Further, the present invention provides an advantageous scheme wherein all the data communications sessions held by the GGSN 200 are kept alive in case of a single point of failure of the GTP-C/m.

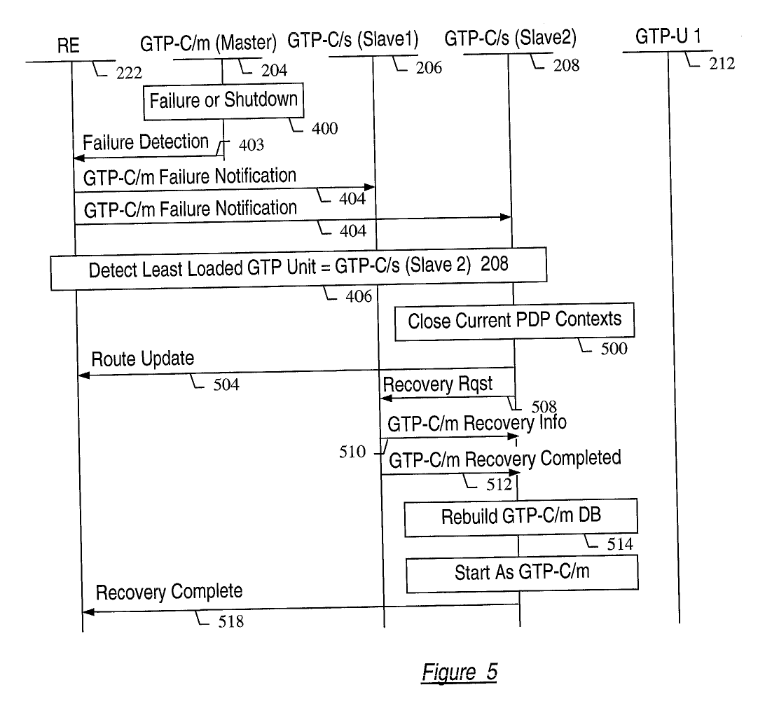

Reference is now made to FIG. 5, wherein there is shown an exemplary nodal operation and signal flow diagram of yet another aspect of the preferred embodiment of the invention directed to a recovery scheme following the failure of the GTP-C/m 204 of the GGSN 200 wherein there is no spare GTP-C unit available in the GGSN. In FIG. 4, the shown exemplary nodal operation and signal flow diagram illustrates the same GGSN 200 having the same components as those described with reference to FIGS. 2 and 3, except for the GTP-C spare. At the beginning, it is assumed that the GGSN 200 functions normally by supporting a number of data communications sessions, as described hereinbefore. At one point in time, the GTP-C/m 204 experiences a failure, or for a given reason is shut down by the operator, action 400. Following the failure or shutdown, via the heartbeat (keep-alive) signal sent by the other GTP-C units, or because of the lack of heartbeat signal (keep-alive) sent by the failed GTP-C/m 204, the RE 222 is informed of the failure or shutdown of the GTP-C 208, action 402. In action 404, the RE 222 informs all the GTP-C units 206 and 208 of the GGSN 200, that the GTP-C/m (master) 204 is down, and in action 407, the GTP-C/s with the least load is detected, which in the present case is assumed to be the GTP-C/s (slave2) 208. Following the election of the GTP-C/s 208 as the least loaded GTP-C, and by consequence its election as a fail-over unit, the GTP-C/s 208 closes all the current data communications sessions related to its active PDP contexts, action 500, and therefore ceases to control data sessions and act as a slave GTP-C/s. Therefore, in action 504, the GTP-C 208 sends a Route Update message to the RE 222 to request the closure of its routes associated with the closed PDP contexts. The GTP-C 208 further transmits a GTP-C/m Recovery Request message 508 to all active GTP-C/s (in the present illustrated exemplary scenario only to GTP-C/s 206), in order to acquire all pertinent information that was originally stored in the GTP-C/m (master) 204 that failed. Responsive to the request 508, the GTP-C/s 208 receives from GTP-C/s 206 a GTP-C/m Recovery Information 510 comprising information related to the identification and control of the data sessions handled by each GTP-C/s, such as for example, but not limited to the Access Point Name (APN), the GTP-U identification of the GTP-U that processes the payload of each session, etc. The GTP-C/s 206 confirms the end of the transmission of the GTP-C/m Recovery Information by a GTP-C/m Recovery Completed message 512. Having received the appropriate GTP-C/m Recovery Information, the GTP-C/s 206 rebuilds the GTP-C/m (master) information database in action 514, and starts acting as a GTP-C/m (master), action 516. Finally, the newly rebuild GTP-C/m 208 sends a Recovery Complete message 518 to the RE 222 for informing of the completion of the rebuild process.

Based upon the foregoing, it should now be apparent to those of ordinary skill in the art that the present invention provides an advantageous solution, which offers GTP-C/m redundancy, by quickly activating a less important GTP-C/s (slave) unit as an active GTP-C/m (master) unit in instances of failure or shutdown of the active GTP-C/m unit. Further, the present invention provides an advantageous scheme wherein most of the data communications sessions held by the plurality of GTP-C/s units of the GGSN 200 are kept alive in case of a single point of failure of the GTP-C/m unit even when no spare GTP-C unit is available, by scarifying only the least loaded GTP-C/s unit in order to recover the GTP-C/m unit, wherein only those data communications sessions controlled by the least loaded, sacrificed GTP-C/s unit are lost.

Although the system and method of the present invention have been described in particular reference to certain radio telecommunications messaging standards, it should be realized upon reference hereto that the innovative teachings contained herein are not necessarily limited thereto and may be implemented advantageously with any applicable radio telecommunications standard. It is believed that the operation and construction of the present invention will be apparent from the foregoing description. The method and system shown and described have are provided as exemplary embodiments of the invention, it will be readily apparent that various changes and modifications could be made therein without departing from the scope of the invention as defined by the claims set forth hereinbelow. For example, while the invention has been described with a given of GTP-C/s units and GTP-U units, it is understood that this number may vary according to the needs of a GGSN given implementation.

Although several preferred embodiments of the method and system of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A method for replacing a failed data session slave control unit (GTP-C/s) in a Gateway General Packet Radio Service (GPRS) Support Node (GGSN), the method comprising the steps of:
detecting a failure or a shutdown of the GTP-C/s in the GGSN;
detecting if the failed GTP-C/s controlled any data sessions before it failed;
if the failed GTP-C/s controlled any data sessions before it failed, closing all the data sessions and accounting sessions related to the data sessions.

2. The method claimed in claim 1, further comprising the steps of:
detecting a presence of a spare, non-utilized, data session control unit (GTFP-C spare) in the GGSN;
assigning to the GTP-C spare a role of GTP-C/s by assigning an IP address previously held by the GTP-C/s that failed to the GTP-C spare; and
starting the GTP-C spare as a GTP-C/s.

3. The method of claim 1, wherein the step of detecting a failure or a shutdown of the GTP-C/s in the GGSN comprises the step of:
detecting in the GGSN a lack of a heartbeat message sent by the failed GTP-C/s.

4. The method claimed in claim 1, wherein the step of detecting if the failed GTP-C/s controlled any data sessions before it failed, comprises the step of:
detecting if the failed GTP-C/s comprises any PDP context before it failed.

5. The method claimed in claim 4, wherein the step of detecting if the failed GTP-C/s comprises any PDP context before it failed, is performed in a master data session control unit (GTP-C/m) of the GGSN.

6. The method claimed in claim 1, wherein the step of closing all the data sessions comprises the steps of:
transmitting from a master data session control unit (GTP-C/m) of the GGSN to each data session payload unit (GTP-U) of the GGSN a Close Session message requesting that all active data sessions controlled by the GTP-C/s that failed be closed; and
closing by each GTP-U of the GGSN all active data sessions controlled by the GTP-C/s that failed.

7. A method for replacing a failed data session master control unit (GTP-C/m) in a Gateway General Packet Radio Service (GPRS) Support Node (GGSN), the method comprising the steps of:
detecting a failure or a shutdown of the GTP-C/m in the GGSN;
detecting, among all remaining data session control units (GTP-C) available in the GGSN, the GTP-C with the least load, and electing the GTP-C with the least load as a fail-over unit for the GTP-C/m that failed;
recovering by the elected fail-over GTP-C information related to the failed GTP-C/m from other GTP-C units;
rebuilding by the elected GTP-C a GTP-C/m information database using the information related to the failed GTP-C/m; and
starting the elected GTP-C as a GTP-C/m of the GGSN.

8. The method claimed in claim 7, wherein the step of detecting a failure or a shutdown of the GTP-C/m in the GGSN comprises the step of:
detecting in the GGSN a lack of a heartbeat message sent by the failed GTP-C/m.

9. The method claimed in claim 7, wherein the step of detecting the GTP-C with the least load, comprises the step of:
sending a GTP-C failure notification to each remaining GTP-C units of the GGSN.

10. The method claimed in claim 7, wherein the GTP-C detected to have the least load is a spare, non-utilized, GTP-C unit of the GGSN.

11. The method claimed in claim 7, wherein the GTP-C detected to have the least load is a slave GTP-C selected among all active slave GTP-Cs of the GGSN.

12. The method claimed in claim 7, further comprising, before the step of recovering, the step of:
closing by the selected slave GTP-C all currently controlled Packet Data Protocol (PDP) Contexts related to its supported data sessions.

13. A Gateway General Packet Radio Service (GPRS) Support Node (GGSN), comprising:
a plurality of slave data session control units (GTP-C/s), each being set to controlling a plurality of data sessions for Mobile Stations (MSs);
a plurality of data sessions payload units (GTP-Us) for supporting a routing of a payload of the data sessions; and
a master data session control unit (GTP-C/m) detecting a failure or a shutdown of one of the GTP-C/s of the GGSN, the GTP-C/m further detecting if the failed GTP-C/s controlled any data sessions before it failed, and if the failed GTP-C/s controlled any data sessions before it failed, the GTP-C/m requesting from the plurality of GTP-Us to close all the data sessions;
wherein the GTP-Us respond to the request by closing all accounting sessions related to the data sessions.

14. The GGSN claimed in claim 13, wherein the GGSN further comprises a spare, non-utilized, data session control unit (GTP-C spare), and wherein:
the GTP-C/m detects a presence of a spare, non-utilized, data session control unit (GTP-C spare) in the GGSN, the GTP-C/m replaces the failed GTP-C/s with the GTP-C spare by assigning an IP address previously held by the GTP-C/s that failed, and a role of GTP-C/s, to the GTP-C spare, and starts the GTP-C spare as a GTP-C/s.

15. The GGSN claimed in claim 13, wherein the GTP-C/m detects the failure or the shutdown of the GTP-C/s by detecting a lack of a heartbeat message sent by the failed GTP-C/s.

16. The GGSN claimed in claim 13, wherein the GTP-C/m detects if the failed GTP-C/s controlled any data sessions before it failed by detecting if the failed GTP-C/s comprises any PDP context before it failed.

17. The GGSN claimed in claim 13, wherein:
the GTP-C/m transmits to each GTP-U of the GGSN a Close Session Request message for requesting that all active data sessions controlled by the GTP-C/s that failed to be closed; and
responsive to the Close Session Request message, each GTP-U of the GGSN close all active data sessions controlled by the GTP-C/s that failed.

18. A Gateway General Packet Radio Service (GPRS) Support Node (GGSN), comprising:
a master data session control unit (GTP-C/m);
a plurality of data session control units (GTP-Cs); and
an Routing Engine (RE) detecting a failure or a shutdown of the GTP-C/m;
wherein the RE in combination with all remaining GTP-Cs available in the GGSN further detects the GTP-C with the least load, and elect the GTP-C with the least load as a fail-over unit for the GTP-C/m that failed, and wherein the elected GTP-C recovers information related to the failed GTP-C/m from the remaining GTP-C units, rebuilds a GTP-C/m information database using the information related to the failed GTP-C/m, and starts acting as a GTP-C/m of the GGSN.

19. The GGSN claimed in claim 18, wherein the RE detects the failure or the shutdown of the GTP-C/m in the GGSN by detecting a lack of a heartbeat message sent by the failed GTP-C/m.

20. The GGSN claimed in claim 18, wherein for detecting the GTP-C with the least load the RE sends a GTP-C failure notification to each remaining GTP-C units of the GGSN.

21. The GGSN claimed in claim 18, wherein the GTP-C detected to have the least load is a spare, non-utilized, GTP-C unit of the GGSN.

22. The GGSN claimed in claim 18, wherein the GTP-C detected to have the least load is a slave GTP-C selected among all active slave GTP-Cs of the GGSN.

23. The GGSN claimed in claim 18, wherein before recovering the information related to the failed GTP-C/m from the remaining GTP-C units, the elected GTP-C closes all currently controlled Packet Data Protocol (PDP) Contexts related to its supported data sessions.
